(19) United States
(12) Patent Application Publication
(10) Pub. No.: US 2025/0173256 A1
(43) Pub. Date: May 29, 2025

(54) MEMORY, OPERATION METHOD THEREOF, AND MEMORY SYSTEM

(71) Applicant: YANGTZE MEMORY TECHNOLOGIES CO., LTD., Wuhan (CN)

(72) Inventors: Danyang LI, Wuhan (CN); Yu WANG, Wuhan (CN); ZhiChao DU, Wuhan (CN)

(21) Appl. No.: 18/597,208

(22) Filed: Mar. 6, 2024

(30) Foreign Application Priority Data
Nov. 28, 2023 (CN) 2023116208314

(51) Int. Cl. G06F 12/02

(52) U.S. Cl. CPC G06F 12/0223

(57) ABSTRACT

Examples of the present disclosure provide a memory, an operation method thereof, and a memory system. The memory comprises a memory cell array and a peripheral circuit coupled to the memory cell array, wherein the memory cell array comprises a plurality of word lines. The operation method comprises: applying a precharge voltage to a selected word line of the plurality of word lines at a first moment; changing a voltage applied to a non-selected word line adjacent to the selected word line from a first voltage to a second voltage at a second moment before the first moment, wherein the first voltage is greater than the second voltage; and applying a voltage pulse to the selected word line at a third moment before the first moment.

### CROSS-REFERENCE TO RELATED APPLICATIONS

The present application claims priority to Chinese Patent Application No. 2023116208314, which was filed Nov. 28, 2023, is titled “A MEMORY AND ITS OPERATING METHOD, MEMORY SYSTEM,” and is hereby incorporated herein by reference in its entirety.

### TECHNICAL FIELD

Examples of the present disclosure relate to the field of semiconductor technologies, and in particular, to a memory, an operation method thereof, and a memory system.

### BACKGROUND

As the density of memories keeps increasing, memory cells have a characteristic of reduced physical sizes. Word lines in a memory are physically closer, and coupling capacitance between adjacent word lines increases.

### SUMMARY

In view of this, examples of the present disclosure provide a memory, an operation method thereof, and a memory system.

In a first aspect, examples of the present disclosure provide an operation method of a memory, the memory comprising: a memory cell array comprising a plurality of word lines; and a peripheral circuit coupled to the memory cell array, wherein the operation method comprises:
applying a precharge voltage to a selected word line of the plurality of word lines at a first moment;
changing a voltage applied to a non-selected word line adjacent to the selected word line from a first voltage to a second voltage at a second moment before the first moment, wherein the first voltage is greater than the second voltage; and
applying a voltage pulse to the selected word line at a third moment before the first moment.

In some examples, the third moment is not earlier than the second moment.

In some examples, the applying a voltage pulse to the selected word line at a third moment before the first moment comprises:
starting to apply a third voltage to the selected word line at the third moment before the first moment, wherein the third voltage is greater than an absolute value of a difference between the first voltage and the second voltage.

In some examples, the applying a voltage pulse to the selected word line at a third moment before the first moment further comprises:
finishing applying the third voltage to the selected word line at a fourth moment after the third moment and before the first moment.

In some examples, duration between the second moment and the first moment is first duration, and duration between the third moment and the fourth moment is second duration, wherein a ratio between the second duration and the first duration is greater than 0.5.

In some examples, the operation method further comprises:
causing the voltage applied on the adjacent non-selected word line to reach the second voltage at a fifth moment after the second moment, wherein duration between the second moment and the fifth moment is third duration, and the third duration is less than or equal to the first duration.

In some examples, the operation method further comprises:
floating the selected word line at a sixth moment after the first moment; and
changing the voltage applied to the adjacent non-selected word line from the second voltage to a fourth voltage at a seventh moment after the first moment and before the sixth moment, wherein the second voltage is less than the fourth voltage.

In some examples, the operation method further comprises:
causing the voltage applied on the adjacent non-selected word line to reach the fourth voltage at an eighth moment after the seventh moment, wherein duration between the seventh moment and the eighth moment is fourth duration, duration between the seventh moment and the sixth moment is fifth duration, and the fourth duration less than or equal to the fifth duration.

In some examples, the first voltage and the fourth voltage are the same.

In some examples, the operation method further comprises:
causing the selected word line to start discharging at a ninth moment after the sixth moment.

In some examples, when the selected word line is an nth word line, the adjacent non-selected word line comprises an (n−1)th word line and an (n+1)th word line, n being a natural number.

In some examples, the adjacent non-selected word line further comprises a word line spaced apart from the selected word line by m word lines, m being a natural number greater than or equal to 1 and less than or equal to 4.

In a second aspect, examples of the present disclosure provide a memory, comprising a memory cell array comprising a plurality of word lines; and a peripheral circuit coupled to the memory cell array,
wherein the peripheral circuit is further configured to:
apply a precharge voltage to a selected word line of the plurality of word lines at a first moment;
change a voltage applied to a non-selected word line adjacent to the selected word line from a first voltage to a second voltage at a second moment before the first moment, wherein the first voltage is greater than the second voltage; and
apply a voltage pulse to the selected word line at a third moment before the first moment.

In some examples, the peripheral circuit comprises a word line driving circuit, a first voltage control circuit, and a second voltage control circuit,
wherein the word line driving circuit is configured to: receive a main word line selective signal and a word line selective signal; cause the adjacent non-selected word line to be connected to the second voltage control circuit at the second moment; and cause the adjacent non-selected word line to be connected to the first voltage control circuit at a seventh moment,
wherein the main word line selective signal is to select one main word line of a plurality of main word lines of the peripheral circuit, each main word line corresponds to the plurality of word lines, and the word line selective signal is to select one word line of the plurality of word lines corresponding to the main word line.

In some examples, the second voltage control circuit is configured to apply the second voltage to the adjacent non-selected word line at the second moment, and
the word line driving circuit is configured to start to apply a third voltage to the selected word line at the third moment not earlier than the second moment, wherein the third voltage is greater than an absolute value of a difference between the first voltage and the second voltage.

In some examples, the word line driving circuit is configured to:
finish applying the third voltage to the selected word line at a fourth moment after the third moment and before the first moment.

In some examples, the word line driving circuit is configured to float the selected word line at a sixth moment after the first moment, and
the first voltage control circuit is configured to apply a fourth voltage to the adjacent non-selected word line at the seventh moment after the first moment and before the sixth moment, wherein the second voltage is less than the fourth voltage.

In some examples, duration between the second moment and the first moment is first duration, and duration between the third moment and the fourth moment is second duration, wherein a ratio between the second duration and the first duration is greater than 0.5.

In some examples, the memory comprises a dynamic random access memory.

In a third aspect, examples of the present disclosure provide a memory system, comprising:
the memory in the above technical solution; and
a controller coupled to the memory and configured to control the memory.

Examples of the present disclosure provide a memory, an operation method thereof, and a memory system. The memory comprises a memory cell array and a peripheral circuit coupled to the memory cell array, wherein the memory cell array comprises a plurality of word lines. The operation method comprises: applying a precharge voltage to a selected word line of the plurality of word lines at a first moment; changing a voltage applied to a non-selected word line adjacent to the selected word line from a first voltage to a second voltage at a second moment before the first moment, wherein the first voltage is greater than the second voltage; and applying a voltage pulse to the selected word line at a third moment before the first moment. In the examples of the present disclosure, before performing precharging on a selected word line, the voltage applied to the adjacent non-selected word line is reduced, and an amplitude of the voltage increase on the adjacent non-selected word line is controlled; and a voltage pulse is applied to the selected word line before performing precharging on the selected word line, and an amplitude of the voltage decrease on the selected word line is controlled, thereby shortening duration of the precharging on the selected word line, and further improving the performance of the memory.

### BRIEF DESCRIPTION OF THE DRAWINGS

FIG. 1 is a waveform graph of a read operation of a memory provided by some examples;

FIG. 2 is a schematic timing diagram of accessing a selected word line provided by an example of the present disclosure;

FIG. 3 is a waveform graph of accessing a selected word line provided by an example of the present disclosure;

FIG. 4 is a flow diagram of an operation method of a memory provided by examples of the present disclosure;

FIG. 5 is a schematic timing diagram of accessing a selected word line provided by another example of the present disclosure;

FIG. 6 is a waveform graph of accessing a selected word line provided by another example of the present disclosure;

FIG. 7 is a comparison diagram of precharge time of accessing a selected word line in two examples of the present disclosure;

FIG. 8 is a schematic structural diagram of a memory provided by examples of the present disclosure;

FIG. 9 is a partial schematic structural diagram of a peripheral circuit provided by examples of the present disclosure;

FIG. 10 is a schematic structural diagram of a memory system provided by examples of the present disclosure; and

FIG. 11 is a schematic structural diagram of an electronic apparatus provided by examples of the present disclosure.

### DETAILED DESCRIPTION

The technical solutions in the examples of the present disclosure will be described clearly and completely in the following in conjunction with the examples of the present disclosure and the accompanying drawings, and it is obvious that the described examples are only a part of the examples of the present disclosure, but not all of the examples. Based on the examples in the present disclosure, all other examples obtained by a person of ordinary skill in the art without creative labor fall within the scope of protection of the present disclosure.

In the following description, numerous specific details are given in order to provide a more thorough understanding of the present disclosure. It will be apparent, however, to one skilled in the art that the present disclosure may be practiced without one or more of these details. In other examples, some technical features well-known in the art are not described to avoid confusion with the present disclosure; that is, not all features of the actual example are described here, and well-known functions and structures are not described in detail.

In the drawings, the size of layers, regions, elements and their relative sizes may be exaggerated for clarity. Like reference numerals refer to like elements throughout.

It will be understood that when an element or layer is referred to as being “on,” “adjacent to,” “connected to” or “coupled to” other elements or layers, it can be directly on, adjacent to, connected to, or coupled to other elements or layers, or intervening elements or layers may be present. In contrast, when an element is referred to as being “directly on,” “directly adjacent to,” “directly connected to” or “directly coupled to” other elements or layers, there are no intervening elements or layers. It will be understood that, although the terms such as first, second, third etc. may be used to describe at least one of various elements, components, regions, layers or sections, at least one of these elements, components, regions, layers or sections should not be limited by these terms. These terms are only used to distinguish one element, component, region, layer or section from another element, component, region, layer or section. Thus, a first element, component, region, layer or section discussed below could be represented as a second element, component, region, layer or section without departing from the teachings of the present disclosure. When a second element, component, region, layer or section is discussed, it does not indicate that a first element, component, region, layer or section exists in the present disclosure.

Spatial relationship terms such as “under”, “below”, “beneath”, “underneath”, “on”, “above” and so on, can be used here for convenience to describe the relationship between one element or feature and other elements or features shown in the figures. It will be understood that the spatially relationship terms also comprise different orientations of the device in use and operation in addition to the orientation depicted in the figures. For example, if the device in the figures is turned over, elements or features described as “below” or “underneath” or “under” other elements or features would then be oriented as “above” the other elements or features. Thus, the example terms “below” and “under” can comprise both orientations of above and below. The device may be otherwise oriented (rotated 90 degrees or at other orientations) and the spatial descriptors used herein may be interpreted accordingly.

The terminology used herein is for the purpose of describing particular examples only and is not to be taken as a limitation of the present disclosure. As used herein, “a”, “an” and “said/the” in singular forms are intended to include the plural forms as well, unless the context clearly dictates otherwise. It should also be understood that at least one of the terms “consists of” or “comprising”, when used in this specification, identify the presence of at least one of stated features, integers, operations, elements or components, but do not exclude presence or addition of at least one of one or more other features, integers, operations, elements, components or groups. As used herein, the term “at least one of . . . ” includes any and all combinations of the associated listed items.

In order to provide a thoroughly understanding of the present disclosure, the detailed operations and structure are described below in order to illustrate the technical solution of the present disclosure. Detailed description of examples of the present disclosure is as follows. However, in addition to these detailed descriptions, the present disclosure may have other examples.

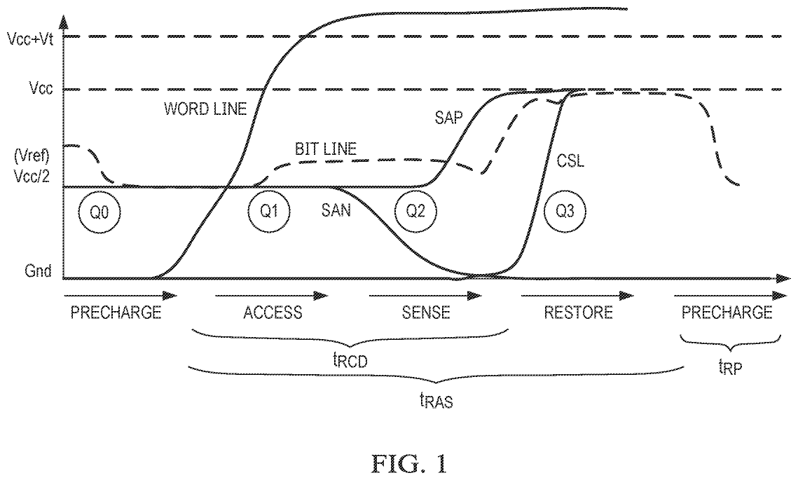

With reference to FIG. 1, FIG. 1 is a waveform graph of a read operation of a memory (memory device) provided by some examples. As shown in FIG. 1, the horizontal coordinate axis represents time, and the vertical coordinate axis represents voltage. The read operation of the memory, for example, a dynamic random access memory (DRAM), comprises: a precharge operation, an access operation, a sense operation, and a restore operation. The precharge operation is performed in stage Q0, the access operation is performed in stage Q1, the sense operation is performed in stage Q2, and the restore operation is performed in stage Q3. Each memory cell in the DRAM comprises a transistor and a memory capacitor. A gate of the transistor is connected to a word line (WL), a drain of the transistor is connected to a bit line (BL), and a source of the transistor is connected to the memory capacitor. The turn-on or turn-off of the transistor is controlled by using the voltage on the word line, and data stored in the memory capacitor is read by using the bit line, or data is written to the memory capacitor by using the bit line for storage. The memory capacitor in the memory cell may store “0” or “1”. FIG. 1 uses a process of reading “1” from the memory capacitor as an example for description.

In the stage Q0, a precharge operation is performed, and the bit line is precharged to a reference voltage Vref, that is, Vcc/2. FIG. 1 shows that the reference voltage Vref=Vcc/2.

In the stage Q1, the access operation is performed to perform charge share. The transistor in the memory cell is turned on. The bit line may access the memory capacitor in the memory cell. Positive charges in the memory capacitor in the memory cell may flow to the bit line, to further pull up the voltage of the bit line, so that charge share occurs between charges in the bit line and charges in the memory capacitor.

In the stage Q2, a sense amplifier (SA) detects and amplifies a voltage difference between a bit line connected to the sense amplifier and a reference bit line. The sense amplifier comprises a P-type control terminal (Sense-Amplifier P-Fet Control, SAP) and an N-type control terminal (Sense-Amplifier N-Fet Control, SAN). The voltage on the SAP is set to a voltage of logic 1, that is, a high voltage Vcc, and the voltage on the bit line is pulled up by the SAP to the high voltage Vcc. The voltage on the SAN is set to a voltage of logic 0, that is, a low voltage Vss, and the voltage on the reference bit line is pulled down by the SAN to the low voltage Vss.

In the stage Q3, the voltage on the bit line is the high voltage Vcc, and in this case, the bit line may charge the memory capacitor. After certain duration, the charges in the memory capacitor may be restored to the state before the read operation. In the stage Q3, the read operation is performed, the column selective transistor is turned on by controlling a column selective signal (Column Selective Line, CSL), and data in the memory capacitor may be outputted by the sense amplifier to an input/output line (IO).

Furthermore, FIG. 1 shows a time (Time of RAS to CAS Delay, t_{RCD}) of a delay of transmission from a row address (Row Address Strobe, RAS) to a column address (Column Address Strobe, CAS) of memory, that is, a sum of duration of the stage Q1 and duration of the stage Q2. FIG. 1 further shows a time of row address strobe (Time of Row Address Strobe, t_{RAS}). Precharge duration (Time of Row Precharge, t_{RP}) is duration of precharging the bit line to the reference voltage.

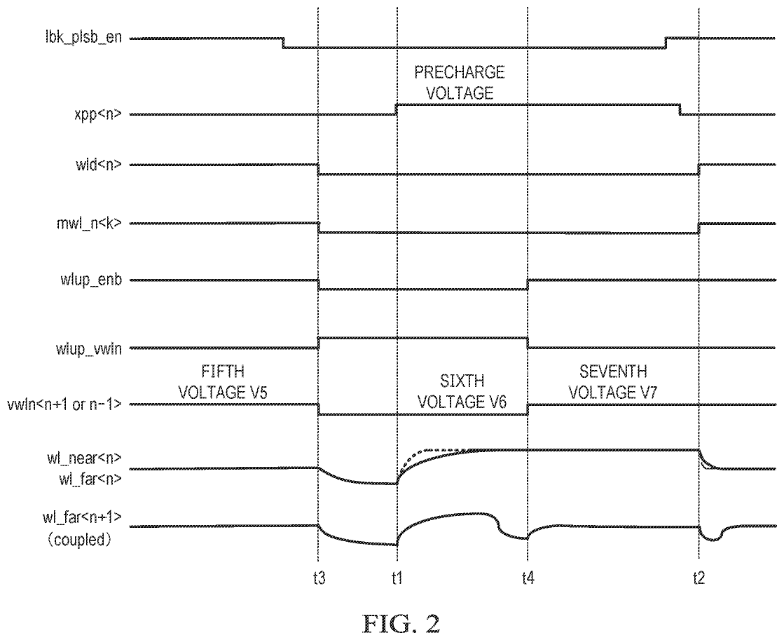

With reference to FIG. 2, FIG. 2 is a schematic timing diagram of accessing a selected word line provided by an example of the present disclosure. As shown in FIG. 2, under triggering of a memory bank selective signal lbk_plsb_en, a main word line selective signal mwl_n<k>, a word line selective signal wld<n>, and a precharge control signal xpp<n>, at a first time node T1, a precharge operation is performed on a selected word line wl<n>. Due to the presence of word line resistance, different durations are required to charge a near end wl_near<n> of the selected word line and a far end wl_far<n> of the selected word line to a precharge voltage Vpp starting from the first time node T1. In FIG. 2, the solid line shows the far end wl_far<n> of the selected word line, the dashed line shows the near end wl_near<n> of the selected word line, and duration required for the voltage on the near end wl_near<n> of the selected word line to reach the precharge voltage Vpp is shorter.

A far end wl_far<n+1> of an adjacent non-selected word line is used as an example for description. In a process of performing a precharge operation on the selected word line wl<n>, due to a coupling effect of word lines, the voltage on the far end wl_far<n+1> of the adjacent non-selected word line also increases. That is, in the process of accessing the selected word line of the memory, the voltage on the selected word line slopes up to a certain voltage value within a short time. As a result, the voltage on the adjacent non-selected word line is coupled to increase.

At a second time node T2 after the first time node T1, the selected word line wl<n> starts discharging. In a process of discharging the selected word line wl<n>, due to the coupling effect of word lines, the voltage on the far end wl_far<n+1> of the adjacent non-selected word line also decreases.

In this case, in the process of accessing the selected word line of the memory, due to the coupling effect of word lines, the adjacent non-selected word line may be interfered, and as a result, the current flows into or flows out of an adjacent memory cell, affecting the reliability of the memory.

Still with reference to FIG. 1, at a third time node T3 before the first time node T1, before the precharge operation is performed on the selected word line wl<n>, a voltage applied by a local word line vwln<n+1 or n−1> to the far end wl_far<n+1> of the adjacent non-selected word line is changed from a fifth voltage V5 to a sixth voltage V6, and the fifth voltage V5 is greater than the sixth voltage V6. In this case, before the precharge operation is performed on the selected word line wl<n>, the voltage applied to the far end wl_far<n+1> of the adjacent non-selected word line is reduced in advance, to reduce impact of the coupling effect of word lines on the voltage on the far end wl_far<n+1> of the adjacent non-selected word line, and reduce an amplitude of the voltage increase on the far end wl_far<n+1> of the adjacent non-selected word line increases.

Still with reference to FIG. 1, at a fourth time node T4 after the first time node T1 and before the second time node T2, before the selected word line wl<n> is discharged, the voltage applied by the local word line vwln<n+1 or n−1> to the far end wl_far<n+1> of the adjacent non-selected word line is changed from the sixth voltage V6 to a seventh voltage V7, and the sixth voltage V6 is less than the seventh voltage V7. In this case, before the selected word line wl<n> is discharged, the voltage applied to the far end wl_far<n+1> of the adjacent non-selected word line is increased in advance, to reduce impact of the coupling effect of word lines on the voltage on the far end wl_far<n+1> of the adjacent non-selected word line, and reduce an amplitude of the voltage decrease on the far end wl_far<n+1> of the adjacent non-selected word line.

In summary, before the selected word line is precharged, the voltage applied to the adjacent non-selected word line is reduced, and the amplitude of the voltage increase on the adjacent non-selected word line is controlled. Before the selected word line is discharged, the voltage applied to the adjacent non-selected word line is increased, and the amplitude of the voltage decrease on the adjacent non-selected word line is controlled. In this case, in the charge-discharge process of the selected word line, the amplitude of the voltage variation of the adjacent non-selected word line can be effectively reduced, to avoid changing stored information of the adjacent memory cell.

However, with reference to FIG. 2, before the selected word line is precharged, the voltage applied to the adjacent non-selected word line is reduced. Due to the coupling effect of word lines, the voltage on the selected word line also decreases. As a result, in a subsequent process of performing the precharge operation on the selected word line, duration required to charge the voltage on the selected word line to the precharge voltage Vpp is longer.

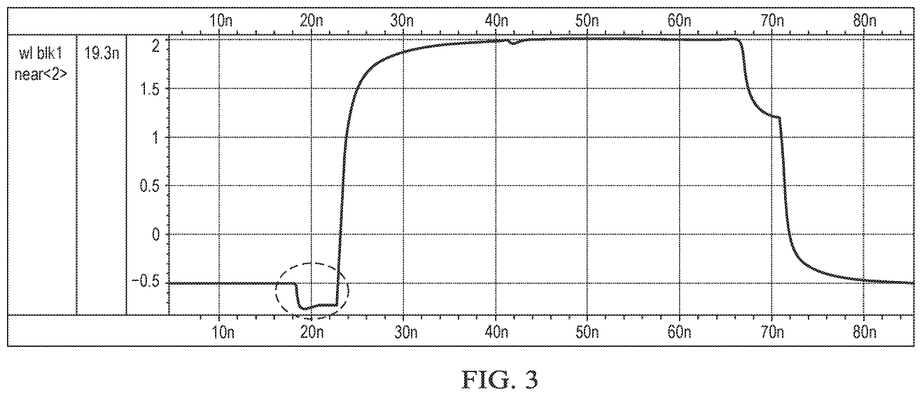

With reference to FIG. 3, FIG. 3 is a waveform graph of accessing a selected word line provided by an example of the present disclosure. As shown in FIG. 3, the horizontal coordinate represents time, and the vertical coordinate represents voltage. As shown by a dashed line round box in FIG. 3, before a precharge operation is performed on a selected word line, a voltage applied to an adjacent non-selected word line is reduced. Due to the coupling effect of word lines, a voltage on the selected word line also decreases. In other words, a start voltage for performing a precharge operation on the selected word line decreases, and as a result, duration of performing a precharge operation on the selected word line increases.

In view of this, examples of the present disclosure provide a memory, an operation method thereof, and a memory system.

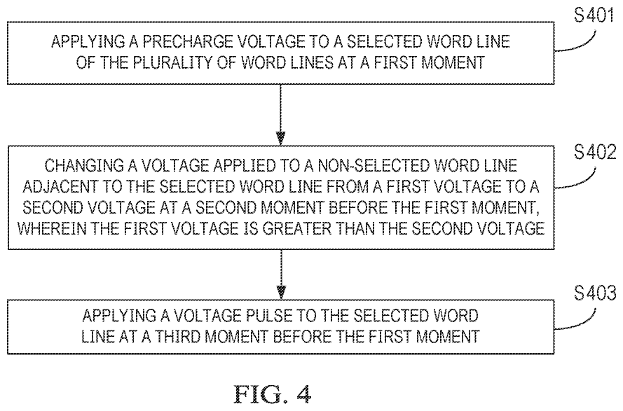

With reference to FIG. 4, FIG. 4 is a flow diagram of an operation method of a memory provided by examples of the present disclosure. As shown in FIG. 4, examples of the present disclosure provide an operation method of a memory, wherein the memory comprises: a memory cell array and a peripheral circuit coupled to the memory cell array, wherein the memory cell array comprises a plurality of word lines, and the above operation method comprises:

Operation S401: Applying a precharge voltage to a selected word line of the plurality of word lines at a first moment.

Operation S402: Changing a voltage applied to a non-selected word line adjacent to the selected word line from a first voltage to a second voltage at a second moment before the first moment, wherein the first voltage is greater than the second voltage.

Operation S403: Applying a voltage pulse to the selected word line at a third moment before the first moment.

In the examples of the present disclosure, before the selected word line is precharged, the voltage applied to the adjacent non-selected word line is reduced, and the amplitude of the voltage increase on the adjacent non-selected word line is controlled; and the voltage pulse is applied to the selected word line before the selected word line is precharged, and the amplitude of the voltage decrease on the selected word line is controlled, to shorten duration of precharging the selected word line, thereby further improving the performance of the memory.

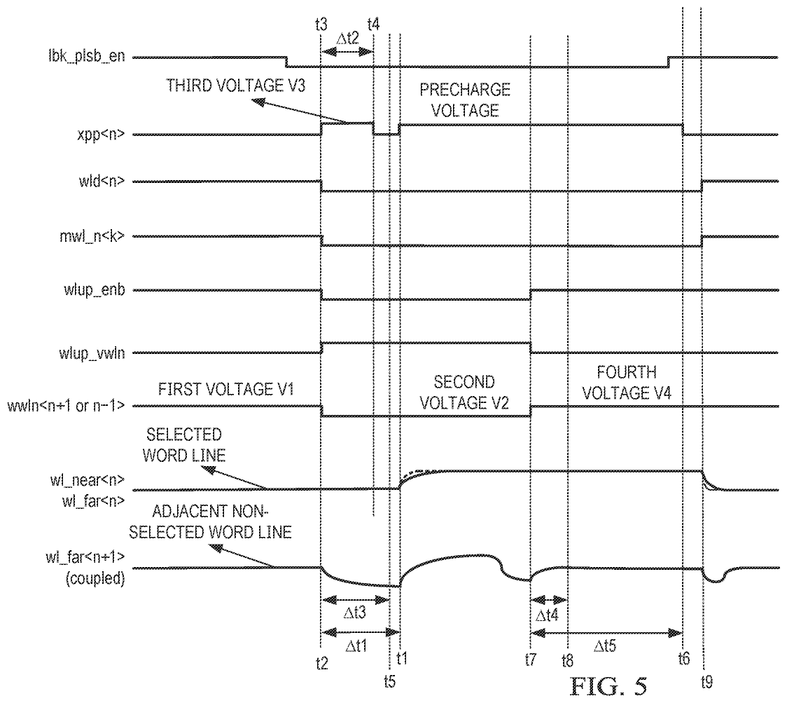

With reference to FIG. 5, FIG. 5 is a schematic timing diagram of accessing a selected word line provided by another example of the present disclosure. As shown in FIG. 5, in operation S401, under triggering of a memory bank selective signal lbk_plsb_en, a main word line selective signal mwl_n<k>, a word line selective signal wld<n>, and a precharge control signal xpp<n>, at a first moment t1, a precharge operation is performed on a selected word line wl<n>. Due to the presence of word line resistance, different durations are required to charge a near end wl_near<n> of the selected word line and a far end wl_far<n> of the selected word line to a precharge voltage Vpp starting from the first moment t1. In FIG. 5, a solid line shows the far end wl_far<n> of the selected word line, a dashed line shows the near end wl_near<n> of the selected word line, and duration for the voltage applied on the near end wl_near<n> of the selected word line to reach the precharge voltage is shorter.

Enabled states of the memory bank selective signal lbk_plsb_en, the main word line selective signal mwl_n<k>, and the word line selective signal wld<n> are all at a low voltage, for example, Vss, and non-enabled states are all high voltages, for example, Vpp or Vdd. An enabled state of the precharge control signal xpp<n> is a high voltage, for example, Vpp or Vdd, and a non-enabled state of the precharge control signal xpp<n> is a low voltage, for example, Vss.

It may be understood that, for the selected word line, the memory bank selective signal lbk_plsb_en, the main word line selective signal mwl_n<k>, and the word line selective signal wld<n> are all in an enabled state, that is, at a low voltage, for example, Vss.

Here, the memory bank selective signal lbk_plsb_en is to select one memory bank of a plurality of memory banks. The main word line selective signal mwl_n<k> is to select one main word line of a plurality of main word lines of the peripheral circuit, and each main word line corresponds to a plurality of word lines; and the word line selective signal wld<n> is to select one word line of the plurality of word lines corresponding to the main word line.

Here, at the first moment t1, a precharge operation is performed on the selected word line wl<n>, that is, the precharge voltage Vpp is applied to the selected word line. For the selected word line, starting from the first moment t1, the voltages on the near end wl_near<n> of the selected word line and the far end wl_far<n> of the selected word line both increase. After certain duration, voltage values on the near end wl_near<n> of the selected word line and the far end wl_far<n> of the selected word line may both reach the voltage value of the precharge voltage.

Still with reference to FIG. 5, the far end wl_far<n+1> of the adjacent non-selected word line is used as an example for description. In Operation S402, at a second moment t2 before the first moment t1, a voltage applied by a local word line vwln<n+1 or n−1> to the far end wl_far<n+1> of the adjacent non-selected word line is changed from a first voltage V1 to a second voltage V2, and the first voltage V1 is greater than the second voltage V2. In this case, before the selected word line wl<n> starts to be precharged at the first moment t1, the voltage applied to the far end wl_far<n+1> of the adjacent non-selected word line is reduced in advance, to reduce impact of the coupling effect of word lines on the voltage on the far end wl_far<n+1> of the adjacent non-selected word line, and reduce the amplitude of the voltage increase on the far end wl_far<n+1> of the adjacent non-selected word line.

It may be understood that, for the adjacent non-selected word line, the memory bank selective signal lbk_plsb_en, the main word line selective signal mwl_n<k>, and the word line selective signal wld<n> are all in non-enabled states, that is, at a high voltage, for example, Vpp.

Still with reference to FIG. 5, in Operation S403, under triggering of a memory bank selective signal lbk_plsb_en, a main word line selective signal mwl_n<k>, a word line selective signal wld<n>, and a precharge control signal xpp<n>, the memory applies a voltage pulse to the selected word line wl<n> at a third moment t3 before the first moment t1. In this case, before the selected word line wl<n> starts to be precharged at the first moment t1, the voltage pulse is applied to the selected word line wl<n> in advance, to control the amplitude of the voltage decrease on the selected word line wl<n> due to the coupling effect of word lines, thereby avoiding an increase in duration of precharging because of a low start voltage on the selected word line wl<n>.

The purpose of applying the voltage pulse the selected word line is to compensate for the voltage decrease on the selected word line due to the coupling effect of word lines. For example, the voltage applied to the adjacent non-selected word line is changed from the first voltage V1 to the second voltage V2, and the value of the voltage decrease on the non-selected word line is the difference between the first voltage V1 and the second voltage V2. In the above-mentioned process, due to the coupling effect of word lines, the value of the voltage decrease on the selected word line is less than or equal to the difference between the first voltage V1 and the second voltage V2. The purpose of applying the voltage pulse to the selected word line is to further reduce or even substantially eliminate the effect that the voltage on the selected word line is coupled to decrease. In this way, it can be avoided that at the first moment t1 (that is, a moment at which the precharge operation starts to be performed), the voltage on the selected word line is low and thereby increasing the duration of precharging.

In some examples, the third moment t3 is not earlier than the second moment t2.

Here, the third moment t3 and the second moment t2 may be the same, or the third moment t3 may be later than the second moment t2. In an example, FIG. 5 shows that the third moment t3 and the second moment t2 are the same.

In some examples, with reference to FIG. 5, Operation S403 comprises: starting to apply a third voltage V3 to the selected word line wl<n> at the third moment t3 before the first moment t1, wherein the third voltage V3 is greater than an absolute value of a difference between the first voltage V1 and the second voltage V2.

Here, at the second moment t2, the voltage applied to the far end wl_far<n+1> of the adjacent non-selected word line is reduced, that is, is reduced from the first voltage V1 to the second voltage V2, and due to the coupling effect of word lines, the voltage on the selected word line wl<n> also starts to decrease at the second moment t2. At the third moment t3, the third voltage V3 starts to be applied to the selected word line wl<n> to reduce the coupling effect of the far end wl_far<n+1> of the adjacent non-selected word line on the selected word line wl<n>, thereby reducing the amplitude of the voltage decrease on the selected word line wl<n> due to the coupling effect of word lines, and further shortening the duration of precharging the selected word line wl<n>.

In some examples, with reference to FIG. 5, at the third moment t3, the third voltage V3 starts to be applied to the selected word line wl<n>. Operation S403 further comprises: at a fourth moment t4, finishing applying the third voltage V3 to the selected word line wl<n>, wherein before a precharge operation is performed on the selected word line wl<n>, duration of applying the voltage pulse to the selected word line wl<n> is (t4-t3).

Here, the fourth moment t4 is later than the second moment t2, and the fourth moment t4 is earlier than the first moment t1. That is, a process of applying the voltage pulse to the selected word line wl<n> is earlier than a process of performing a precharge operation on the selected word line wl<n>. In an example, the magnitude and duration of the voltage pulse applied on the selected word line may be flexibly selected according to the coupling effect of the adjacent non-selected word line on the selected word line.

In some examples, with reference to FIG. 5, duration between the second moment t2 and the first moment t1 is first duration Δt1, that is, (t1-t2). Duration between the third moment t3 and the fourth moment t4 is second duration Δt2, that is, (t4-t3). A ratio between the second duration Δt2 and the first duration Δt1 is greater than 0.5.

Here, the first duration Δt1 refers to duration of applying the second voltage V2 to the far end wl_far<n+1> of the adjacent non-selected word line at before a precharge operation is performed on the selected word line wl<n>. In other words, the first duration refers to duration of pulling down the voltage on the far end wl_far<n+1> of the adjacent non-selected word line before the precharge operation is performed on the selected word line wl<n>. Alternatively, the first duration refers to duration of pulling down the voltage on the selected word line wl<n> due to the word line coupling effect of the far end wl_far<n+1> of the adjacent non-selected word line on the selected word line wl<n>. The second duration Δt2 refers to duration of applying the voltage pulse to the selected word line wl<n>.

If the ratio between the second duration and the first duration is excessively small, the impact on the voltage on the selected word line may be limited, and it is difficult to control the amplitude of the voltage decrease on the selected word line due to the coupling effect of word lines.

In some examples, the voltage on the selected word line wl<n> at the second moment t2 and the voltage on the selected word line wl<n> at the first moment t1 are substantially the same.

Here, “substantially the same” refers to that a difference between the voltage on the selected word line wl<n> at the second moment t2 and the voltage on the selected word line wl<n> at the first moment t1 is less than a preset value. In a particular example, the difference between the voltage on the selected word line wl<n> at the second moment t2 and the voltage on the selected word line wl<n> at the first moment t1 is 0.

In this way, the voltage pulse is applied to the selected word line before a precharge operation is performed on the selected word line, so that the coupling effect of the voltage decrease on the non-selected word line on the voltage on the selected word line can be effectively reduced or even substantially eliminated, thereby improving a start voltage for performing a precharge operation on the selected word line, and further improving the duration of precharging the selected word line.

In some examples, with reference to FIG. 5, at a fifth moment t5, the voltage applied on the adjacent non-selected word line (for example, the far end wl_far<n+1> of the adjacent non-selected word line) reaches the second voltage V2. Duration between the second moment t2 and the fifth moment t5 is third duration Δt3, that is, (t5-t2). The third duration Δt3 is less than or equal to the first duration Δt1.

In this way, the third duration is set to ensure that the voltage on the adjacent non-selected word line already reaches the second voltage before the selected word line is precharged, to further improve a control effect of the voltage change of the adjacent non-selected word line in the process of precharging the selected word line.

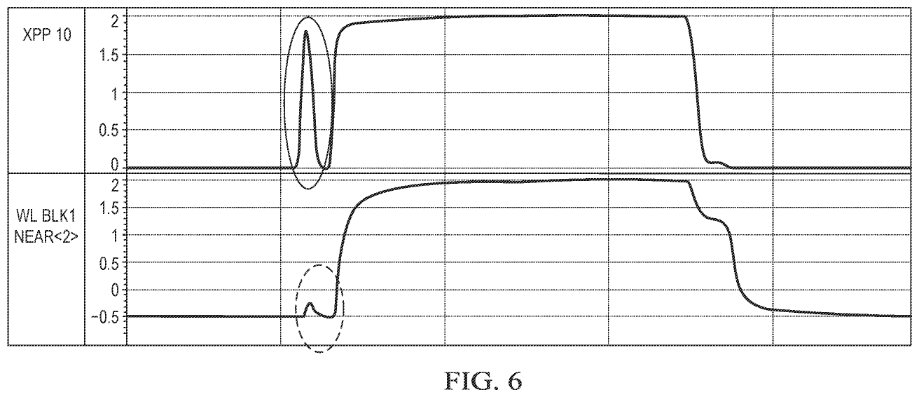

With reference to FIG. 6, FIG. 6 is a waveform graph of accessing a selected word line provided by another example of the present disclosure. As shown in FIG. 6, the horizontal coordinate represents time, and the vertical coordinate represents voltage. As shown by the solid line round box in FIG. 6, before a precharge operation is performed on the selected word line, a voltage pulse is applied to the selected word line. As shown by the dashed line round box in FIG. 6, the voltage pulse is applied to the selected word line to cause the voltage on the selected word line to substantially remain unchanged before the precharge operation is performed, or to reduce an amplitude of the voltage decrease on the selected word line before a precharge operation is performed.

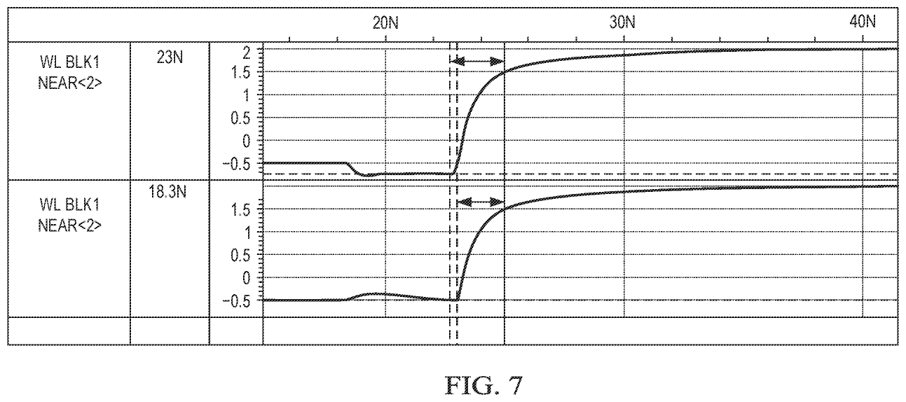

With reference to FIG. 7, FIG. 7 is a comparison diagram of precharge time of accessing a selected word line in two examples of the present disclosure. As shown in FIG. 7, the horizontal coordinate represents time, and the vertical coordinate represents voltage. FIG. 7 shows that the voltage pulse is not applied to the selected word line before the precharge operation is performed on the selected word line, and in this case, a start voltage for performing the precharge operation on the selected word line is lower, and the duration of precharging is longer. FIG. 7 further shows that the voltage pulse is applied to the selected word line before the precharge operation is performed on the selected word line, and in this case, a start voltage for performing the precharge operation on the selected word line is higher, and the duration of precharging is shorter. That is, the amplitude of the voltage decrease on the selected word line may be controlled by applying the voltage pulse to the selected word line before the selected word line is precharged, thereby shortening duration of precharging the selected word line, and further improving the performance of the memory.

In some examples, the above operation method further comprises:
starting floating the selected word line at a sixth moment t6 after the first moment t1; and
changing the voltage applied to the adjacent non-selected word line from the second voltage V2 to a fourth voltage V4 at a seventh moment t7 after the first moment t1 and before the sixth moment t6, wherein the second voltage V2 is less than the fourth voltage V4.

With reference to FIG. 5, at the sixth moment t6 after the first moment t1, the precharge control signal xpp<n> is switched from an enabled state to a non-enabled state, and the precharge operation on the selected word line wl<n> is stopped, and the selected word line wl<n> starts to be floated.

In some examples, with reference to FIG. 5, at the sixth moment t6, the selected word line wl<n> starts to be floated, and at a ninth moment t9 after certain buffering time from the sixth moment t6, the selected word line wl<n> starts discharging.

A far end wl_far<n+1 or n−1> of the adjacent non-selected word line is used as an example for description. At the seventh moment t7 after the first moment t1 and before the sixth moment t6, a voltage applied by the local word line vwln<n+1 or n−1> to the far end wl_far<n+1 or n−1> of the adjacent non-selected word line is changed from the second voltage V2 to the fourth voltage V4, wherein the second voltage V2 is less than the fourth voltage V4. In this way, before the selected word line wl<n> starts to be floated at the sixth moment t6, the voltage applied to the far end wl_far<n+1 or n−1> of the adjacent non-selected word line is increased in advance, to reduce impact of the coupling effect of word lines on the voltage on the far end wl_far<n+1 or n−1> of the adjacent non-selected word line, and reduce the amplitude of the voltage decrease on the far end wl_far<n+1 or n−1> of the adjacent non-selected word line.

In summary, before performing the precharge operation on the selected word line, the voltage applied to the adjacent non-selected word line is reduced in advance, and the amplitude of the voltage increase on the adjacent non-selected word line is controlled. The amplitude of the voltage decrease on the adjacent non-selected word line can be controlled by increasing the voltage applied to the adjacent non-selected word line in advance before the selected word line is discharged. In this case, in the charge-discharge process of the selected word line, the amplitude of the voltage variation on the adjacent non-selected word line can be effectively reduced.

In some examples, with reference to FIG. 5, at an eighth moment t8, the voltage on the adjacent non-selected word line (for example, the far end wl_far<n+1> of the adjacent non-selected word line) reaches the fourth voltage V4, wherein duration between the seventh moment t7 and the eighth moment t8 is fourth duration Δt4, that is, (t8-t7), and duration between the seventh moment t7 and the sixth moment t6 is fifth duration Δt5, that is, (t6-t7); and the fourth duration Δt4 is less than or equal to the fifth duration Δt5.

In this way, the fourth duration is set to ensure that the voltage on the adjacent non-selected word line already reaches the fourth voltage before the selected word line starts discharging, to further improve a control effect of the voltage variation on the adjacent non-selected word line in a process of discharging the selected word line.

In some examples, the first voltage V1 and the fourth voltage V4 are the same.

In some examples, the first voltage V1, the second voltage V2, and the fourth voltage V4 are all negative voltages.

In a particular example, the first voltage V1 and the fourth voltage V4 may both be negative voltages vwln, for example, −0.5 V; and the second voltage V2 may be a negative voltage vwln2, for example, −1 V.

In some examples, when the selected word line is an nth word line, the adjacent non-selected word line comprises an (n−1)th word line and an (n+1)th word line, and n is a natural number.

In an example, when the selected word line is an eighth word line, the adjacent non-selected word line comprises a seventh word line and a ninth word line.

In some examples, the adjacent non-selected word line further comprises a word line spaced apart from the selected word line by m word lines, and m is a natural number greater than or equal to 1 and less than or equal to 4.

In an example, when the selected word line is the eighth word line, the adjacent non-selected word line further comprises a word line spaced apart from the selected word line by one word line, that is, the sixth word line and the tenth word line; the adjacent non-selected word line further comprises a word line spaced apart from the selected word line by two word lines, that is, the fifth word line and the eleventh word line; the adjacent non-selected word line further comprises a word line spaced apart from the selected word line by three word lines, that is, the fourth word line and the twelfth word line; and the adjacent non-selected word line further comprises a word line spaced apart from the selected word line by four word lines, that is, the third word line and the thirteenth word line.

The adjacent non-selected word line may comprise a plurality of word lines, and when a distance between the adjacent non-selected word line and the selected word line is smaller, the coupling effect of the adjacent non-selected word line on the selected word line is stronger. In practice, in an example, the magnitude and duration of a voltage pulse applied to the selected word line before a precharge operation is performed on the selected word line may be selected according to the strength of the coupling effect of the adjacent non-selected word line on the selected word line.

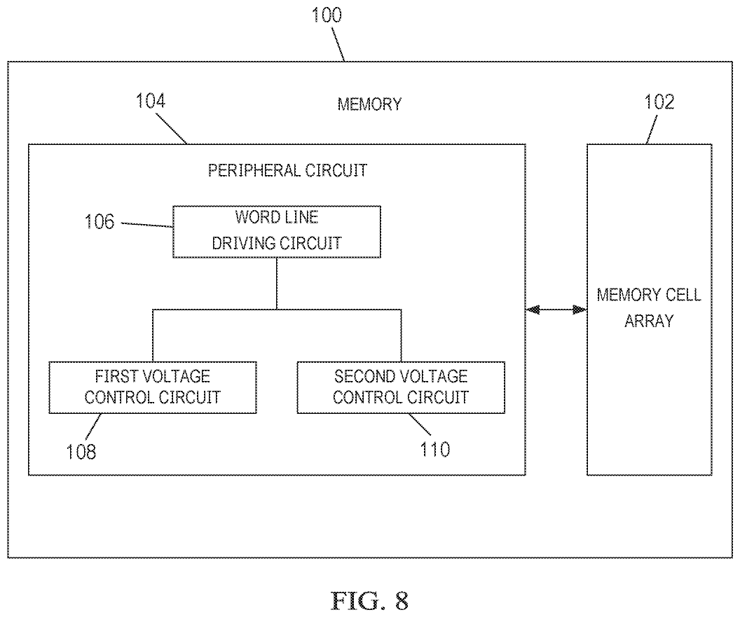

With reference to FIG. 8, FIG. 8 is a schematic structural diagram of a memory provided by examples of the present disclosure. As shown in FIG. 8, examples of the present disclosure provide a memory. The memory 100 comprises a memory cell array 102 and a peripheral circuit 104 coupled to the memory cell array 102, wherein the memory cell array 102 comprises a plurality of word lines.

The above-mentioned peripheral circuit 104 is configured to:
apply a precharge voltage to a selected word line of the plurality of word lines at a first moment;
change a voltage applied to a non-selected word line adjacent to the selected word line from a first voltage to a second voltage at a second moment before the first moment, wherein the first voltage is greater than the second voltage; and
apply a voltage pulse to the selected word line at a third moment before the first moment.

In the examples of the present disclosure, the peripheral circuit may be configured to: before a selected word line is precharged, reduce a voltage applied to an adjacent non-selected word line, and control the amplitude of the voltage increase on the adjacent non-selected word line; and the peripheral circuit may be configured to: apply a voltage pulse to the selected word line before the selected word line is precharged, and control the amplitude of the voltage decrease on the selected word line, to shorten duration of precharging the selected word line, thereby further improving the performance of the memory.

In some examples, the peripheral circuit 104 comprises a word line driving circuit 106, a first voltage control circuit 108, and a second voltage control circuit 110; and
the word line driving circuit 106 is configured to: receive a main word line selective signal mwl_n<k> and a word line selective signal wld<n>, cause the adjacent non-selected word line to be connected to the second voltage control circuit 110 at the second moment, and cause the adjacent non-selected word line to be connected to the first voltage control circuit 108 at a seventh moment,
wherein the main word line selective signal mwl_n<k> is to select one main word line of a plurality of main word lines of the peripheral circuit, each main word line corresponds to the plurality of word lines, and the word line selective signal wld<n> is to select one word line of the plurality of word lines corresponding to the main word line.

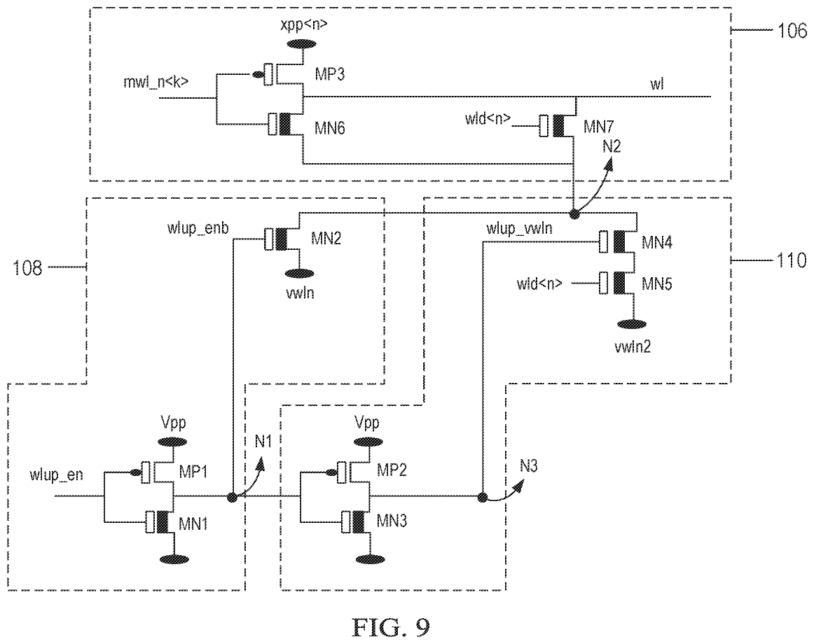

With reference to FIG. 5 and FIG. 9, an example in which the first voltage V1 and the fourth voltage V4 are the same is used for description. At a second moment t2, the adjacent non-selected word line is connected to the second voltage control circuit 110, and the second voltage control circuit 110 transfers the second voltage V2, that is, a negative voltage vwln2, to the adjacent non-selected word line in response to a second control signal wlup_vwln. At a seventh moment t7, the adjacent non-selected word line is connected to the first voltage control circuit 108, and the first voltage control circuit 108 transfers the fourth voltage V4 (or, the first voltage V1), that is, a negative voltage vwln, to the adjacent non-selected word line in response to a first control signal wlup_enb.

In some examples, the second voltage control circuit 110 is configured to apply the second voltage to the adjacent non-selected word line at the second moment, and
the word line driving circuit 106 is configured to start to apply a third voltage to the selected word line at the third moment not earlier than the second moment, wherein the third voltage is greater than an absolute value of a difference between the first voltage and the second voltage.

In some examples, the word line driving circuit 106 is configured to:
finish applying the third voltage to the selected word line at a fourth moment after the third moment and before the first moment.

In some examples, the word line driving circuit 106 is configured to float the selected word line at a sixth moment after the first moment, and
the first voltage control circuit 108 is configured to apply a fourth voltage to the adjacent non-selected word line at the seventh moment after the first moment and before the sixth moment, wherein the second voltage is less than the fourth voltage.

In some examples, duration between the second moment and the first moment is first duration, and

duration between the third moment and the fourth moment is second duration, wherein a ratio between the second duration and the first duration is greater than 0.5.

With reference to FIG. 9, FIG. 9 is a partial schematic structural diagram of a peripheral circuit provided by examples of the present disclosure. As shown in FIG. 9, the peripheral circuit comprises a word line driving circuit 106, a first voltage control circuit 108, and a second voltage control circuit 110.

The word line driving circuit 106 comprises a third P-type transistor MP3, a sixth N-type transistor MN6, and a seventh N-type transistor MN7.

The third P-type transistor MP3 is connected in series to the sixth N-type transistor MN6. A control terminal of the third P-type transistor MP3 is connected to a control terminal of the sixth N-type transistor MN6, and is configured to receive a main word line selective signal mwl_n<k>. A source terminal of the third P-type transistor MP3 is configured to receive a precharge control signal xpp<n>. A drain terminal of the third P-type transistor MP3 and a drain terminal of the seventh N-type transistor MN7 are connected, and are jointly connected to a word line wl. A source terminal of the sixth N-type transistor MN6 is connected to a second node N2.

A control terminal of the seventh N-type transistor MN7 is configured to receive a word line selective signal wld<n>. The drain terminal of the seventh N-type transistor MN7 is connected to the word line wl. A source terminal of the seventh N-type transistor MN7 is connected to the second node N2.

With reference to FIG. 5 and FIG. 9, an enabled state of the precharge control signal xpp<n> is a high voltage, for example, Vpp or Vdd. In this case, the main word line selective signal mwl_n<k> and the word line selective signal wld<n> are both at a low voltage, for example, Vss. At a third moment t3, when the precharge control signal xpp<n> is in an enabled state, the voltage pulse is applied to the selected word line. At a first moment t1, when the precharge control signal xpp<n> is in an enabled state, a precharge operation may be performed on the selected word line.

For the selected word line, in this case, the main word line selective signal mwl_n<k> and the word line selective signal wld<n> are both in the enabled state, that is, at a low voltage, for example, Vss. That is, in this case, the third P-type transistor MP3 in the word line driving circuit 106 is in a turn-on state, the sixth N-type transistor MN6 and the seventh N-type transistor MN7 are both in a turn-off state, a voltage pulse may be applied to the selected word line at the third moment t3, and a precharge voltage may be applied to the selected word line at the first moment t1.

The first voltage control circuit 108 may comprise a first P-type transistor MP1, a first N-type transistor MN1, and a second N-type transistor MN2.

The first P-type transistor MP1 is connected in series to the first N-type transistor MN1. In an example, a control terminal of the first P-type transistor MP1 is connected to a control terminal of the first N-type transistor MN1, and is configured to receive an enable control signal wlup_en. A source terminal of the first P-type transistor MP1 is configured to receive a high voltage, for example, Vpp. A drain terminal of the first P-type transistor MP1 and a drain terminal of the first N-type transistor MN1 are connected, and are jointly connect to a first node N1. The drain terminal of the first P-type transistor MP1 and the drain terminal of the first N-type transistor MN1 are configured to output a first control signal wlup_enb. A source terminal of the first N-type transistor MN1 is configured to receive a low voltage.

A control terminal of the second N-type transistor MN2 is configured to receive the first control signal wlup_enb, a drain terminal of the second N-type transistor MN2 is connected to the second node N2, and a source terminal of the second N-type transistor MN2 is configured to receive a low voltage, for example, the negative voltage vwln.

With reference to FIG. 5 and FIG. 9, an enabled state of the first control signal wlup_enb is a high voltage, for example, Vpp, and a non-enabled state of the first control signal wlup_enb is a low voltage, for example, the negative voltage vwln. When the first control signal wlup_enb is in an enabled state, for example, at a seventh moment t7, the first voltage control circuit 108 is connected to the adjacent non-selected word line, and the first voltage control circuit 108 transfers a fourth voltage V4 (or, a first voltage V1), that is, the negative voltage vwln, to the adjacent non-selected word line in response to the first control signal wlup_enb.

For the adjacent non-selected word line, in this case, the main word line selective signal mwl_n<k> and the word line selective signal wld<n> are both in the non-enabled state, that is, at a high voltage, for example, Vpp. That is, in this case, the seventh N-type transistor MN7 is in a turn-on state, and at the seventh moment t7, the first voltage control circuit 108 may transfer the fourth voltage V4 to the adjacent non-selected word line.

The second voltage control circuit 110 may comprise a second P-type transistor MP2, a third N-type transistor MN3, a fourth N-type transistor MN4, and a fifth N-type transistor MN5.

The second P-type transistor MP2 is connected in series to the third N-type transistor MN3. In an example, a control terminal of the second P-type transistor MP2 and a control terminal of the third N-type transistor MN3 are connected, and are jointly connected to the first node N1. The control terminals of the second P-type transistor MP2 and the third N-type transistor MN3 are configured to receive the first control signal wlup_enb. A source terminal of the second P-type transistor MP2 is configured to receive a high voltage, for example, Vpp. A drain terminal of the second P-type transistor MP2 and a drain terminal of the third N-type transistor MN3 are connected, and are jointly connect to a third node N3. The drain terminal of the second P-type transistor MP2 and the drain terminal of the third N-type transistor MN3 are configured to output a second control signal wlup_vwln. A source terminal of the third N-type transistor MN3 is configured to receive a low voltage.

A control terminal of the fourth N-type transistor MN4 is configured to receive the second control signal wlup_vwln, a drain terminal of the fourth N-type transistor MN4 is connected to the second node N2, and a source terminal of the fourth N-type transistor MN4 is connected to a drain terminal of the fifth N-type transistor MN5. A control terminal of the fifth N-type transistor MN5 is configured to receive the word line selective signal wld<n>, and a source terminal of the fifth N-type transistor MN5 is configured to receive a low voltage, for example, a negative voltage vwln2.

With reference to FIG. 5 and FIG. 9, an enabled state of the second control signal wlup_vwln is a high voltage, for example, Vpp, and a non-enabled state of the second control signal wlup_vwln is a low voltage, for example, a negative voltage vwln. When the second control signal wlup_vwln is in the enabled state, for example, at a second moment t2, the second voltage control circuit is connected to the adjacent non-selected word line, and the second voltage control circuit transfers a second voltage V2, that is, the negative voltage vwln2, to the adjacent non-selected word line in response to the second control signal wlup_vwln.

For the adjacent non-selected word line, in this case, the main word line selective signal mwl_n<k> and the word line selective signal wld<n> are both in the non-enabled state, that is, at a high voltage, for example, Vpp. That is, in this case, the fifth N-type transistor MN5 and the seventh N-type transistor MN7 are in a turn-on state, and at a seventh moment t7, the second voltage control circuit 110 may transfer the second voltage V2 to the adjacent non-selected word line.

In addition, FIG. 9 only shows an example of the peripheral circuit. In the examples of the present disclosure, for the word line driving circuit, the types and connection manners of the transistors in the first voltage control circuit and the second voltage control circuit are not limited, and may be flexibly selected according to an actual case.

In some examples, the memory 100 comprises a dynamic random access memory.

In some examples, memory of the dynamic random access memory meets DDR2 memory specifications.

In some examples, memory of the dynamic random access memory meets DDR3 memory specifications.

In some examples, memory of the dynamic random access memory meets DDR4 memory specifications.

In some examples, memory of the dynamic random access memory meets DDR5 memory specifications.

In some examples, memory of the dynamic random access memory meets LPDDR4 memory specifications.

In some examples, memory of the dynamic random access memory meets LPDDR5 memory specifications.

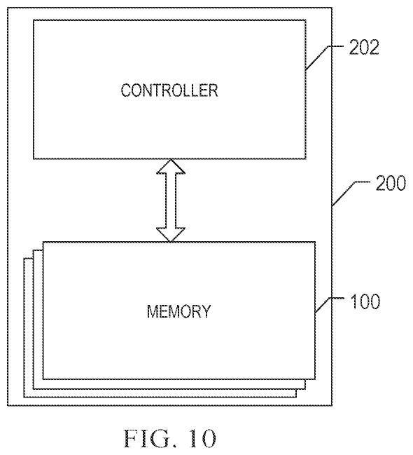

With reference to FIG. 10, FIG. 10 is a schematic structural diagram of a memory system provided by examples of the present disclosure. As shown in FIG. 10, examples of the present disclosure provide a memory system 200. The memory system 200 comprises:
the memory 100 in the above technical solution; and
a controller 202 coupled to the memory 100 and configured to control the memory 100.

In some examples, the controller 202 may send/receive at least one of a command/address signal C/A, a clock signal CLK, a control signal CTRL, data DQ, or a data strobe signal DQS to the memory 100/from the memory 100. The controller 202 may be configured to control operations of the memory 100, for example, read and program operations.

In some examples, the controller 202 may provide an interface with regard to the memory 100 to manage data stored in the memory 100. The controller 202 may further communicate with an external device (for example, a host) according to particular communicate protocols. For example, the controller 202 may communicate with the external apparatus through at least one of various interface protocols, such as a USB protocol, an MMC protocol, a Peripheral Component Interconnect (PCI) protocol, a PCI Express (PCI-E) protocol, an Advanced Technology Attachment (ATA) protocol, a Serial-ATA protocol, a Parallel-ATA protocol, a Small Computer System Interface (SCSI) protocol, an Enhanced Small Drive Interface (ESDI) protocol, an Integrated Drive Electronics (IDE) protocol, a Firewire protocol, etc.

In some examples, the controller 202 may be implemented as a standalone chip, or may be integrated with the memory 100. The controller 202 and one or more memories 100 may be integrated in various types of memory apparatuses. That is, the memory system 200 can be implemented and packaged into different types of end electronic products.

In some examples, the memory may be used as a buffer in the memory system.

In some particular example, the memory (for example, a DRAM) may be for auxiliary use in a solid-state drive, which can make improvements on the solid-state drive, such as reading and writing. Current high-end solid-state drive products mostly select an embedded DRAM to improve the performance of the products, and improve the random read and write speed. In an example, when writing files, especially when writing small files, the small files are stored in a Flash after being processed by the DRAM, such that the solid-state drive has higher storage efficiency and faster speed.

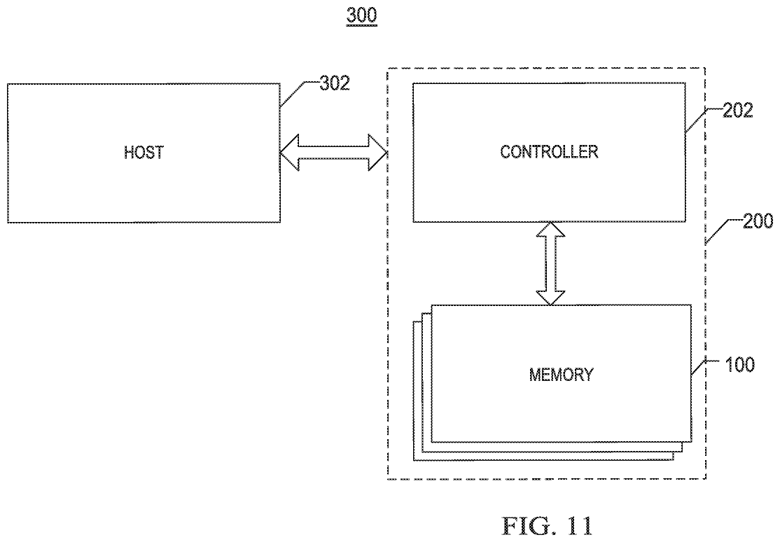

With reference to FIG. 11, FIG. 11 is a schematic structural diagram of an electronic apparatus provided by examples of the present disclosure. As shown in FIG. 11, examples of the present disclosure provide an electronic apparatus 300. The above electronic apparatus 300 comprises: the memory system 200 in the above technical solution; and a host 302 coupled to the memory system 200.

In some examples, the electronic apparatus 300 may be a mobile phone, a desktop computer, a laptop, a tablet, a vehicle computer, a gaming console, a printer, a positioning device, a wearable electronic device, a smart sensor, a virtual reality (VR) device, an augmented reality (AR) device, or any other suitable electronic device having storage therein.

As shown in FIG. 11, the electronic apparatus 300 may comprise a host 302 and a memory system 200. The memory system 200 has one or more memories 100 and a controller 202. The host 302 may be a processor (for example, a central processing unit (CPU) or a system on a chip (SoC) (for example, an application processor (AP)) of an electronic device. The host 302 may be configured to send data to the memory 100 or receive data from the memory 100.

In some examples, the controller 202 is coupled to the memory 100 and the host 302, and is configured to control the memory 100. The controller 202 may manage data stored in the memory 100 and communicate with the host 302.

Examples of the present disclosure provide a memory, an operation method thereof, and a memory system. The memory comprises a memory cell array and a peripheral circuit coupled to the memory cell array, wherein the memory cell array comprises a plurality of word lines. The operation method comprises: applying a precharge voltage to a selected word line of the plurality of word lines at a first moment; changing a voltage applied to a non-selected word line adjacent to the selected word line from a first voltage to a second voltage at a second moment before the first moment, wherein the first voltage is greater than the second voltage; and applying a voltage pulse to the selected word line at a third moment before the first moment. In the examples of the present disclosure, before performing precharging on a selected word line, the voltage applied to the adjacent non-selected word line is reduced, and an amplitude of the voltage increase on the adjacent non-selected word line is controlled; and a voltage pulse is applied to the selected word line before performing precharging on the selected word line, and an amplitude of the voltage decrease on the selected word line is controlled, thereby shortening duration of the precharging on the selected word line, and further improving the performance of the memory.

References to “one example” or “an example” throughout this specification mean that particular features, structures, or characteristics related to the example are comprised in at least one example of the present disclosure. Therefore, appearance of “in one example” or “in an example” throughout this specification does not refer to the same example. Furthermore, these particular features, structures, or characteristics may be incorporated in one or more examples in any suitable manner. In various examples of the present disclosure, sequence numbers of the above processes do not indicate an execution sequence, and an execution sequence of various processes shall be determined by functionalities and intrinsic logics thereof, and shall constitute no limitation on an implementation process of the examples of the present disclosure. The above sequence numbers of the examples of the present disclosure are only for description, and do not represent the merits of the examples.

The above descriptions are merely examples of the present disclosure, and not intended to limit the patent scope of the present disclosure. Equivalent structure transformation made within using the specification and the drawings of the present disclosure under the inventive concept of the present disclosure, or direct/indirect application to other related technical fields are both encompassed within the patent protection scope of the present disclosure.

What is claimed is:

1. An operation method of a memory, the memory comprising:
a memory cell array comprising a plurality of word lines; and
a peripheral circuit coupled to the memory cell array,
wherein the operation method comprises:
applying a precharge voltage to a selected word line of the plurality of word lines at a first moment;
changing a voltage applied to a non-selected word line adjacent to the selected word line from a first voltage to a second voltage at a second moment before the first moment, wherein the first voltage is greater than the second voltage; and
applying a voltage pulse to the selected word line at a third moment before the first moment.

2. The operation method of the memory of claim 1, wherein the third moment is not earlier than the second moment.

3. The operation method of the memory of claim 1, wherein applying the voltage pulse to the selected word line at the third moment before the first moment comprises:
starting to apply a third voltage to the selected word line at the third moment before the first moment, wherein the third voltage is greater than an absolute value of a difference between the first voltage and the second voltage.

4. The operation method of the memory of claim 3, wherein applying the voltage pulse to the selected word line at the third moment before the first moment further comprises:
finishing applying the third voltage to the selected word line at a fourth moment after the third moment and before the first moment.

5. The operation method of the memory of claim 4, wherein a duration between the second moment and the first moment is a first duration, and a duration between the third moment and the fourth moment is a second duration, wherein a ratio between the second duration and the first duration is greater than 0.5.

6. The operation method of the memory of claim 5, wherein the operation method further comprises:
causing the voltage applied on the adjacent non-selected word line to reach the second voltage at a fifth moment after the second moment, wherein a duration between the second moment and the fifth moment is a third duration, and the third duration is less than or equal to the first duration.

7. The operation method of the memory of claim 1, wherein the operation method further comprises:
floating the selected word line at a sixth moment after the first moment; and
changing the voltage applied to the adjacent non-selected word line from the second voltage to a fourth voltage at a seventh moment after the first moment and before the sixth moment, wherein the second voltage is less than the fourth voltage.

8. The operation method of the memory of claim 7, wherein the operation method further comprises:
causing the voltage applied on the adjacent non-selected word line to reach the fourth voltage at an eighth moment after the seventh moment, wherein a duration between the seventh moment and the eighth moment is a fourth duration, a duration between the seventh moment and the sixth moment is a fifth duration, and the fourth duration less than or equal to the fifth duration.

9. The operation method of the memory of claim 7, wherein the first voltage and the fourth voltage are the same.

10. The operation method of the memory of claim 7, wherein the operation method further comprises:
causing the selected word line to start discharging at a ninth moment after the sixth moment.

11. The operation method of the memory of claim 1, wherein when the selected word line is an nth word line, the adjacent non-selected word line comprises an (n−1)th word line and an (n+1)th word line, n being a natural number.

12. The operation method of the memory of claim 11, wherein the adjacent non-selected word line further comprises a word line spaced apart from the selected word line by m word lines, m being a natural number greater than or equal to 1 and less than or equal to 4.

13. A memory, comprising:
a memory cell array comprising a plurality of word lines; and
a peripheral circuit coupled to the memory cell array,
wherein the peripheral circuit is further configured to:
apply a precharge voltage to a selected word line of the plurality of word lines at a first moment;
change a voltage applied to a non-selected word line adjacent to the selected word line from a first voltage to a second voltage at a second moment before the first moment, wherein the first voltage is greater than the second voltage; and
apply a voltage pulse to the selected word line at a third moment before the first moment.

14. The memory of claim 13, wherein the peripheral circuit comprises:
a first voltage control circuit;
a second voltage control circuit; and
a word line driving circuit configured to:
receive a main word line selective signal and a word line selective signal;
cause the adjacent non-selected word line to be connected to the second voltage control circuit at the second moment; and
cause the adjacent non-selected word line to be connected to the first voltage control circuit at a seventh moment,
wherein the main word line selective signal is to select one main word line of a plurality of main word lines of the peripheral circuit, each main word line of the plurality of main word lines corresponds to the plurality of word lines, and the word line selective signal is to select one word line of the plurality of word lines corresponding to the main word line.

15. The memory of claim 14, wherein the second voltage control circuit is configured to: apply the second voltage to the adjacent non-selected word line at the second moment, and the word line driving circuit is configured to:
start to apply a third voltage to the selected word line at the third moment not earlier than the second moment, wherein the third voltage is greater than an absolute value of a difference between the first voltage and the second voltage.

16. The memory of claim 15, wherein the word line driving circuit is configured to:
finish applying the third voltage to the selected word line at a fourth moment after the third moment and before the first moment.

17. The memory of claim 16, wherein the word line driving circuit is configured to:
float the selected word line at a sixth moment after the first moment, and
the first voltage control circuit is configured to:
apply a fourth voltage to the adjacent non-selected word line at the seventh moment after the first moment and before the sixth moment, wherein the second voltage is less than the fourth voltage.

18. The memory of claim 16, wherein a duration between the second moment and the first moment is a first duration, and a duration between the third moment and the fourth moment is a second duration, wherein a ratio between the second duration and the first duration is greater than 0.5.

19. The memory of claim 13, comprising a dynamic random access memory.

20. A memory system, comprising:
a memory, comprising:
a memory cell array comprising a plurality of word lines; and
a peripheral circuit coupled to the memory cell array,
wherein the peripheral circuit is further configured to:
apply a precharge voltage to a selected word line of the plurality of word lines at a first moment;
change a voltage applied to a non-selected word line adjacent to the selected word line from a first voltage to a second voltage at a second moment before the first moment, wherein the first voltage is greater than the second voltage; and
apply a voltage pulse to the selected word line at a third moment before the first moment; and
a controller coupled to the memory and configured to control the memory.
